(19) United States
(12) Patent Application Publication
(10) Pub. No.: US 2025/0344577 A1
(43) Pub. Date: Nov. 6, 2025

(54) DISPLAY DEVICE, METHOD OF MANUFACTURING THE SAME, AND ELECTRONIC DEVICE

(71) Applicant: Samsung Display Co., LTD., Yongin-si (KR)

(72) Inventors: KWANG SOO BAE, Yongin-si (KR); GUN HEE KIM, Yongin-si (KR); GEE-BUM KIM, Yongin-si (KR); HYOENG-KI KIM, Yongin-si (KR); BOKWANG SONG, Yongin-si (KR); BYUNG HAN YOO, Yongin-si (KR)

(73) Assignee: Samsung Display Co., LTD., Yongin-si (KR)

(21) Appl. No.: 19/091,293

(22) Filed: Mar. 26, 2025

(30) Foreign Application Priority Data
May 3, 2024 (KR) 10-2024-0059106

(51) Int. Cl. H10K 59/122; H01L 25/16; H10H 29/01; H10H 29/37; H10K 59/12

(52) U.S. Cl. CPC H10K 59/122; H01L 25/167; H10H 29/012; H10H 29/37; H10K 59/1201

(57) ABSTRACT

A display device includes a circuit element layer including a thin film transistor, a pixel electrode disposed on the circuit element layer, electrically connected to the thin film transistor, and including a central portion, an outer portion outside the central portion, and a first emission portion between the central portion and the outer portion, an insulating pattern disposed between the circuit element layer and the central portion of the pixel electrode, a pixel defining pattern disposed on the central portion of the pixel electrode, a pixel defining layer disposed on the circuit element layer and the pixel electrode, covering the outer portion of the pixel electrode, and exposing the first emission portion of the pixel electrode, an intermediate layer disposed on the pixel electrode, the pixel defining pattern, and the pixel defining layer and including an emission layer, and a common electrode disposed on the intermediate layer.

### CROSS-REFERENCE TO RELATED APPLICATION(S)

This application claims priority to and benefits of Korean Patent Application No. 10-2024-0059106 under 35 U.S.C. § 119, filed on May 3, 2024, in the Korean Intellectual Property Office (KIPO), the entire contents of which are incorporated herein by reference.

### BACKGROUND

### 1. Technical Field

Embodiments relate to a display device, method of manufacturing the same, and an electronic device including the same.

### 2. Description of the Related Art

Flat panel display devices are replacing cathode ray tube display devices as display devices due to their lightweight and thin characteristics. As representative examples of such flat panel display devices, there are liquid crystal display devices and organic light emitting diode display devices.

An electrode of a light emitting element and other metal wires included in a display device may reflect light introduced from the outside. Therefore, the display device may have a problem in that visibility is low due to reflection of external light in a bright environment. To solve the problem, color filters may be disposed in an upper portion of the display device.

### SUMMARY

Embodiments provide a display device with improved display quality.

Embodiments also provide a method of manufacturing a display device with improved display quality.

Embodiments also provide an electronic device including the display device.

Additional features of the disclosure will be set forth in the description which follows, and in part will be apparent from the description, or may be learned by practice of the disclosure.

A display device according to an embodiment may include a circuit element layer including a thin film transistor, a pixel electrode disposed on the circuit element layer, electrically connected to the thin film transistor, and including a central portion, an outer portion outside the central portion in a plan view, and a first emission portion between the central portion and the outer portion, an insulating pattern disposed between the circuit element layer and the central portion of the pixel electrode, a pixel defining pattern disposed on the central portion of the pixel electrode, a pixel defining layer disposed on the circuit element layer and the pixel electrode, covering the outer portion of the pixel electrode, and exposing the first emission portion of the pixel electrode, an intermediate layer disposed on the pixel electrode, the pixel defining pattern, and the pixel defining layer and including an emission layer, and a common electrode disposed on the intermediate layer.

In an embodiment, the pixel defining pattern may cover the central portion of the pixel electrode and may expose the first emission portion of the pixel electrode.

In an embodiment, in a plan view, each of the insulating pattern and the pixel defining pattern may have an island pattern shape, and the pixel defining layer may surround the central portion of the pixel electrode and the first emission portion of the pixel electrode.

In an embodiment, in a plan view, the first emission portion may surround the central portion, and the outer portion may surround the first emission portion.

In an embodiment, the central portion of the pixel electrode may be spaced apart from the intermediate layer with the pixel defining pattern interposed between the central portion of the pixel electrode and the intermediate layer. The outer portion of the pixel electrode may be spaced apart from the intermediate layer with the pixel defining layer interposed between the outer portion of the pixel electrode and the intermediate layer. The first emission portion of the pixel electrode may contact the intermediate layer.

In an embodiment, in a plan view, the pixel defining layer may be spaced apart from the pixel defining pattern and may surround the pixel defining pattern.

In an embodiment, in a plan view, the first emission portion of the pixel electrode may be located outside the insulating pattern. The insulating pattern may include a flat portion and an inclined portion outside the flat portion.

In an embodiment, the pixel electrode may further include a second emission portion between the central portion and the first emission portion. The central portion of the pixel electrode may be located on the flat portion of the insulating pattern, and the second emission portion of the pixel electrode may be located on the inclined portion of the insulating pattern.

In an embodiment, the second emission portion of the pixel electrode may be inclined along an inclined surface of the inclined portion of the insulating pattern and may contact the intermediate layer.

In an embodiment, the pixel defining pattern may cover the central portion of the pixel electrode and may expose the second emission portion of the pixel electrode.

In an embodiment, in a plan view, the second emission portion may surround the central portion, and the first emission portion may surround the second emission portion.

In an embodiment, the display device may further include an insulating layer disposed between the circuit element layer and the outer portion of the pixel electrode and between the circuit element layer and the pixel defining layer. The insulating layer may include a flat portion and an inclined portion outside the flat portion in a plan view. The first emission portion of the pixel electrode may be located between the insulating pattern and the insulating layer.

In an embodiment, in a plan view, each of the insulating pattern and the pixel defining pattern may have an island pattern shape, and each of the insulating layer and the pixel defining layer may surround the central portion of the pixel electrode and the first emission portion of the pixel electrode.

In an embodiment, in a plan view, the insulating layer may be spaced apart from the insulating pattern and may surround the insulating pattern.

In an embodiment, the pixel electrode may further include a third emission portion between the outer portion and the first emission portion. The outer portion of the pixel electrode may be located on the flat portion of the insulating layer, and the third emission portion of the pixel electrode may be located on the inclined portion of the insulating layer.

In an embodiment, the third emission portion of the pixel electrode may be inclined along an inclined surface of the inclined portion of the insulating layer and may contact the intermediate layer.

In an embodiment, the pixel defining layer may expose the third emission portion of the pixel electrode.

In an embodiment, in a plan view, the third emission portion may surround the first emission portion, and the outer portion may surround the third emission portion.

In an embodiment, the display device may further include an encapsulation layer disposed on the common electrode, a light blocking layer disposed on the encapsulation layer in a cross-sectional view and overlapping the pixel defining layer in a plan view, a light blocking pattern disposed on the encapsulation layer in a cross-sectional view and overlapping the pixel defining pattern in a plan view, and a color filter disposed on the encapsulation layer in a cross-sectional view and overlapping the pixel electrode in a plan view.

A method of manufacturing a display device according to an embodiment may include forming, on a substrate, a circuit element layer including a thin film transistor, forming an insulating pattern on the circuit element layer, forming, on the circuit element layer, a pixel electrode including a central portion on the insulating pattern, an outer portion outside the central portion in a plan view, and an emission portion between the central portion and the outer portion, forming a preliminary insulating layer on the circuit element layer and the pixel electrode, forming a pixel defining pattern on the central portion of the pixel electrode and a pixel defining layer covering the outer portion of the pixel electrode and exposing the emission portion of the pixel electrode by patterning the preliminary insulating layer, forming, on the pixel electrode, the pixel defining pattern, and the pixel defining layer, an intermediate layer including an emission layer, and forming a common electrode on the intermediate layer.

An electronic device according to an embodiment may include a display device and a power supply configured to provide power to the display device. The display device may include a circuit element layer including a thin film transistor, a pixel electrode disposed on the circuit element layer, electrically connected to the thin film transistor, and including a central portion, an outer portion outside the central portion in a plan view, and a first emission portion between the central portion and the outer portion, an insulating pattern disposed between the circuit element layer and the central portion of the pixel electrode, a pixel defining pattern disposed on the central portion of the pixel electrode, a pixel defining layer disposed on the circuit element layer and the pixel electrode, covering the outer portion of the pixel electrode, and exposing the first emission portion of the pixel electrode, an intermediate layer disposed on the pixel electrode, the pixel defining pattern, and the pixel defining layer and including an emission layer, and a common electrode disposed on the intermediate layer.

According to embodiments, a reflection of external light of the display device may be reduced and a brightness of the display device may be improved. Therefore, a display quality of the display device may be improved.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure, and together with the description serve to explain the disclosure.

FIG. 1 is a plan view illustrating a display device according to an embodiment.

FIG. 2 is a plan view illustrating a unit pixel area of the display device of FIG. 1.

FIG. 3 is a schematic cross-sectional view taken along line I-I′ of FIG. 2.

FIG. 4 is an enlarged schematic cross-sectional view illustrating area B of FIG. 3.

FIGS. 5 to 7 are enlarged plan views illustrating area A of FIG. 2.

FIGS. 8 to 13 are schematic cross-sectional views illustrating a method of manufacturing the display device of FIG. 3.

FIG. 14 is a schematic cross-sectional view illustrating a display device according to an embodiment.

FIG. 15 is an enlarged schematic cross-sectional view illustrating area C of FIG. 14.

FIGS. 16 to 21 are schematic cross-sectional views illustrating a method of manufacturing the display device of FIG. 14.

FIG. 22 is a schematic block diagram illustrating an electronic device according to an embodiment.

### DETAILED DESCRIPTION OF THE EMBODIMENTS

Various example embodiments will be described more fully hereinafter with reference to the accompanying drawings, in which some example embodiments are shown. The disclosure may, however, be embodied in many different forms and should not be construed as limited to the example embodiments set forth herein. Rather, these example embodiments are provided so that this disclosure will be thorough and complete, and will fully convey the scope of the disclosure to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the disclosure. As used herein, the term “and/or” includes any and all combinations of one or more of the associated listed items.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing particular example embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

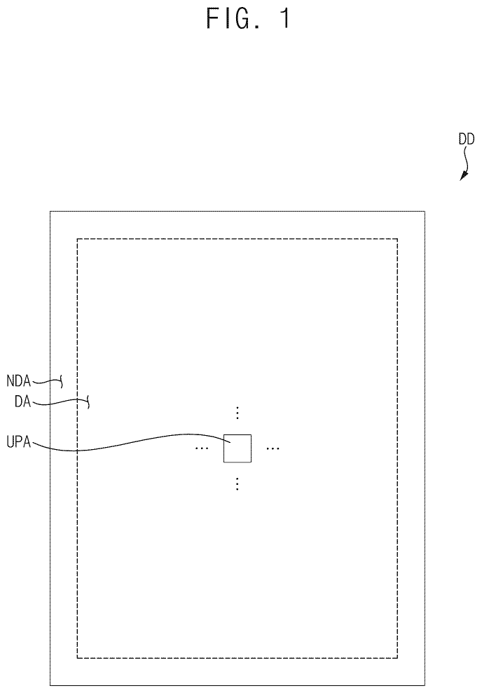

FIG. 1 is a plan view illustrating a display device according to an embodiment.

Referring to FIG. 1, a display device DD according to an embodiment may include a display area DA and a non-display area NDA. An image may be displayed in the display area DA. Multiple light emitting elements that emit light and multiple circuit elements for driving the light emitting elements may be disposed in the display area DA.

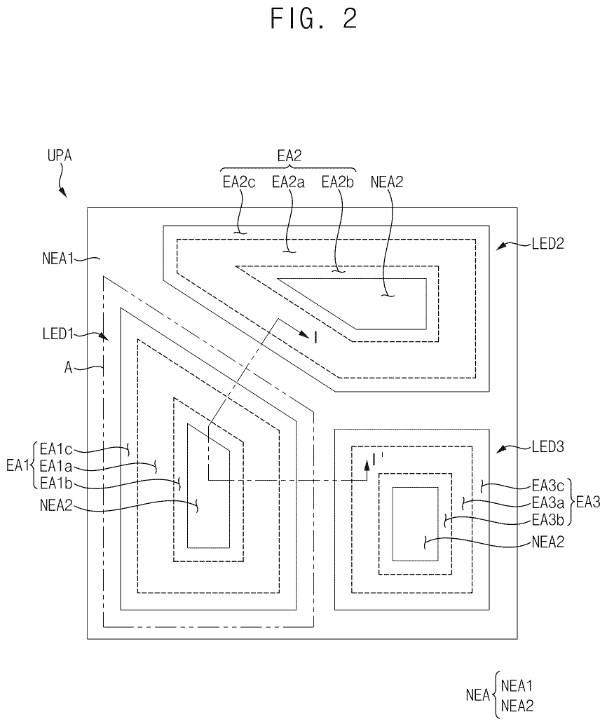

The display area DA may include multiple unit pixel areas UPA. Each of the unit pixel areas UPA may include emission areas (e.g., first to third emission areas EA1, EA2, and EA3 of FIG. 2) that emit light of different colors. In an embodiment, the unit pixel areas UPA may be disposed in a matrix form in the display area DA, but the disclosure is not limited thereto. The light emitted from the unit pixel areas UPA may be combined to generate an image.

The non-display area NDA may be located adjacent to the display area DA. In an embodiment, the non-display area NDA may surround the display area DA in a plan view. A driver configured to provide driving signals to the display area DA may be disposed in the non-display area NDA. The driving signals may include various signals for driving the light emitting elements and the circuit elements, such as a driving voltage, a gate signal, a data signal, or the like.

FIG. 2 is a plan view illustrating a unit pixel area of the display device of FIG. 1.

Referring to FIGS. 1 and 2, in an embodiment, each of the unit pixel areas UPA included in the display area DA may include first to third emission areas EA1, EA2, and EA3 and a non-emission area NEA. The non-emission area NEA may include a first non-emission area NEA1 and multiple second non-emission areas NEA2.

First to third light emitting elements LED1, LED2, and LED3 may be disposed in the first to third emission areas EA1, EA2, and EA3, respectively. The first to third emission areas EA1, EA2, and EA3 may emit light of different colors. For example, the first emission area EA1 may emit red light, the second emission area EA2 may emit green light, and the third emission area EA3 may emit blue light, but the disclosure is not limited thereto.

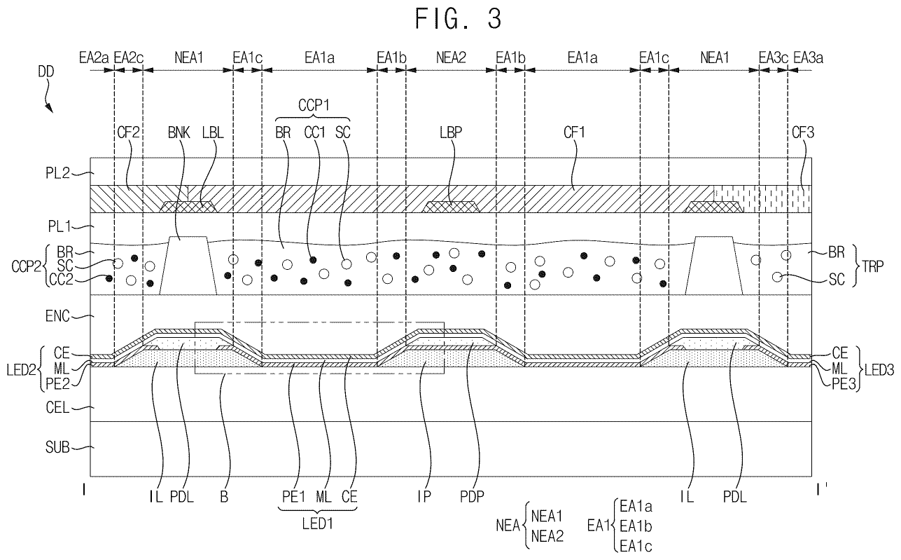

In an embodiment, the first to third light emitting elements LED1, LED2, and LED3 may emit light of a same color. For example, the first to third light emitting elements LED1, LED2, and LED3 may emit blue light. The blue light emitted from the first light emitting element LED1 and the blue light emitted from the second light emitting element LED2 may be respectively converted into red light and green light by a color conversion layer and may be emitted. This will be described in detail below with reference to FIG. 3.

The first to third emission areas EA1, EA2, and EA3 may be spaced apart from each other. The first non-emission area NEA1 may be located between the first to third emission areas EA1, EA2, and EA3 adjacent to each other. For example, the first non-emission area NEA1 may have a grid shape in a plan view.

In a plan view, the second non-emission area NEA2 may be located inside each of the first to third emission areas EA1, EA2, and EA3. Each of the first to third emission areas EA1, EA2, and EA3 may surround a corresponding second non-emission area NEA2 in a plan view. For example, each of the first to third emission areas EA1, EA2, and EA3 may have a ring shape in a plan view. FIG. 2 illustrates that the first emission area EA1 has a hollow trapezoidal shape, the second emission area EA2 has a hollow pentagonal shape, and the third emission area EA3 has a hollow rectangular shape in a plan view, but the disclosure is not limited thereto. For example, each of the first to third emission areas EA1, EA2, and EA3 may have various ring shapes, such as a hollow polygonal shape, a hollow circular shape, a hollow elliptical shape, or the like in a plan view. In each of the unit pixel areas UPA, the first to third emission areas EA1, EA2, and EA3 may be disposed side by side in a direction.

In an embodiment, the first emission area EA1 may include a first-first emission area EA1a, a first-second emission area EA1b, and a first-third emission area EA1c. Each of the first-first emission area EA1a, the first-second emission area EA1b, and the first-third emission area EA1c may have a ring shape in a plan view. In a plan view, the first-second emission area EA1b may surround a corresponding second non-emission area NEA2, the first-first emission area EA1a may surround the first-second emission area EA1b, and the first-third emission area EA1c may surround the first-first emission area EA1a. Each of the second and third emission areas EA2 and EA3 may have a structure similar to the first emission area EA1.

In an embodiment, the second emission area EA2 may include a second-first emission area EA2a, a second-second emission area EA2b, and a second-third emission area EA3c. Each of the second-first emission area EA2a, the second-second emission area EA2b, and the second-third emission area EA2c may have a ring shape in a plan view. In a plan view, the second-second emission area EA2b may surround a corresponding second non-emission area NEA2, the second-first emission area EA2a may surround the second-second emission area EA2b, and the second-third emission area EA2c may surround the second-first emission area EA2a.

In an embodiment, the third emission area EA3 may include a third-first emission area EA3a, a third-second emission area EA3b, and a third-third emission area EA3c. Each of the third-first emission area EA3a, the third-second emission area EA3b, and the third-third emission area EA3c may have a ring shape in a plan view. In a plan view, the third-second emission area EA3b may surround a corresponding second non-emission area NEA2, the third-first emission area EA3a may surround the third-second emission area EA3b, and the third-third emission area EA3c may surround the third-first emission area EA3a.

Hereinafter, the first emission area EA1 and the first light emitting element LED1 disposed in the first emission area EA1 will be described in more detail with reference to FIGS. 2 to 7. Descriptions of the first emission area EA1 and the first light emitting element LED1 may be substantially equally or similarly applied to the second and third emission areas EA2 and EA3 and the second and third light emitting elements LED2 and LED3.

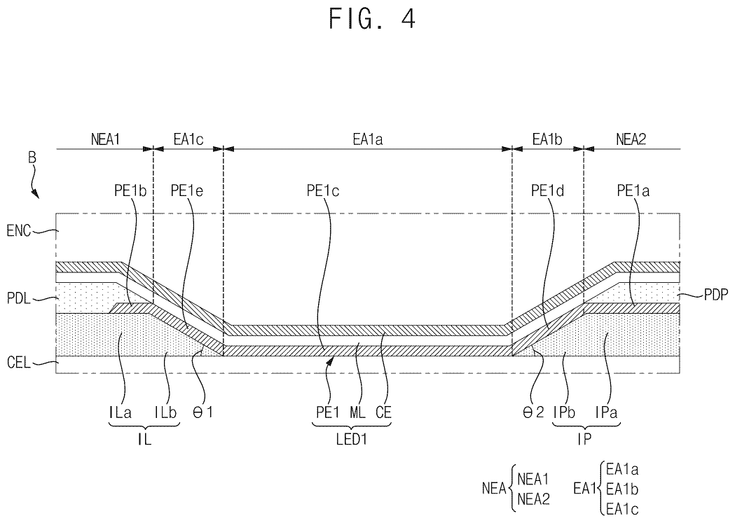

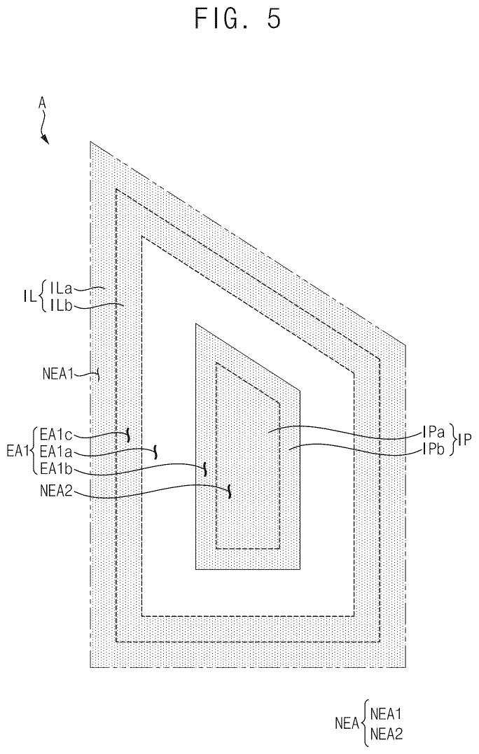

FIG. 3 is a schematic cross-sectional view taken along line I-I′ of FIG. 2. FIG. 4 is an enlarged schematic cross-sectional view illustrating area B of FIG. 3. FIGS. 5 to 7 are enlarged plan views illustrating area A of FIG. 2.

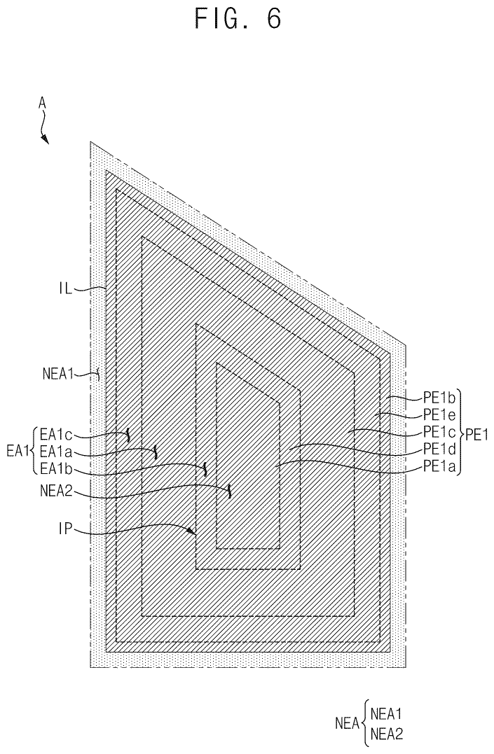

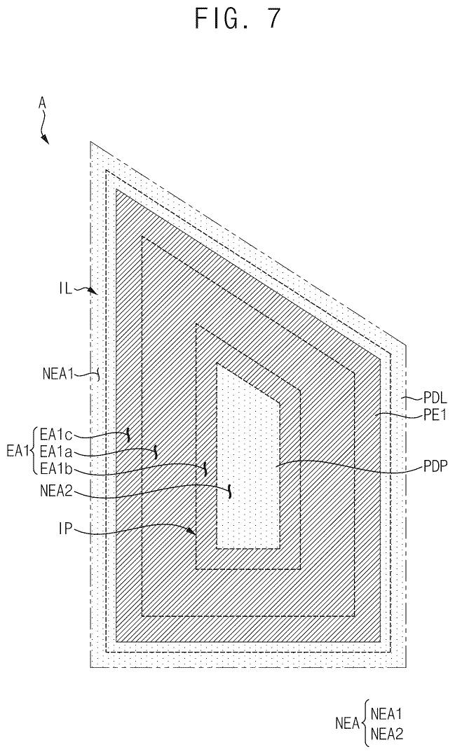

FIG. 5 schematically illustrates an insulating layer IL and an insulating pattern IP in an area around the first emission area EA1. FIG. 6 schematically illustrates a state in which a first pixel electrode PE1 is additionally disposed in the first emission area EA1 of FIG. 5. FIG. 7 schematically illustrates a state in which a pixel defining layer PDL and a pixel defining pattern PDP are additionally disposed in the first emission area EA1 of FIG. 6.

Referring to FIGS. 2 to 7, in an embodiment, the display device DD may include a substrate SUB, a circuit element layer CEL, an insulating layer IL, an insulating pattern IP, first to third pixel electrodes PE1, PE2, and PE3, a pixel defining layer PDL, a pixel defining pattern PDP, an intermediate layer ML, a common electrode CE, an encapsulation layer ENC, a color conversion layer, a first protective layer PL1, a color filter layer, and a second protective layer PL2. The first pixel electrode PE1, the intermediate layer ML, and the common electrode CE may form the first light emitting element LED1. The second pixel electrode PE2, the intermediate layer ML, and the common electrode CE may form the second light emitting element LED2. The third pixel electrode PE3, the intermediate layer ML, and the common electrode CE may form the third light emitting element LED3.

The substrate SUB may be an insulating substrate formed of a transparent or opaque material. In an embodiment, the substrate SUB may include glass, and the display device DD may be a rigid display device. In another embodiment, the substrate SUB may include plastic, and the display device DD may be a flexible display device.

The circuit element layer CEL may be disposed on the substrate SUB. The circuit element layer CEL may include first to third circuit elements respectively electrically connected to the first to third light emitting elements LED1, LED2, and LED3 and at least one insulating layer. Each of the first to third circuit elements may include at least one thin film transistor. The first circuit element may be electrically connected to the first pixel electrode PE1, the second circuit element may be electrically connected to the second pixel electrode PE2, and the third circuit element may be electrically connected to the third pixel electrode PE3. In an embodiment, the circuit element layer CEL may include a via insulating layer covering the first to third circuit elements.

The insulating layer IL and the insulating pattern IP may be disposed on the circuit element layer CEL. The insulating layer IL and the insulating pattern IP may be disposed on the via insulating layer.

The insulating layer IL may be disposed in the first non-emission area NEA1. The insulating layer IL may be further disposed in the first-third emission area EA1c. In a plan view, the insulating layer IL may surround the first-first emission area EA1a. In an embodiment, the insulating layer IL may have a grid shape in a plan view.

The insulating layer IL may include a flat portion ILa and an inclined portion ILb. The flat portion ILa of the insulating layer IL may have a substantially flat upper surface. The inclined portion ILb of the insulating layer IL may be located outside the flat portion ILa. An upper surface of the inclined portion ILb of the insulating layer IL may be an inclined surface that is inclined with respect to each of the upper surface of the flat portion ILa and an upper surface of the circuit element layer CEL (e.g., an upper surface of the via insulating layer).

In an embodiment, a first inclination angle θ1, defined as an angle between the upper surface of the inclined portion ILb of the insulating layer IL and the upper surface of the circuit element layer CEL (e.g., the upper surface of the via insulating layer), may be in a range of about 10 degrees to about 70 degrees.

In an embodiment, the flat portion ILa of the insulating layer IL may correspond to the first non-emission area NEA1, and the inclined portion ILb of the insulating layer IL may correspond to the first-third emission area EA1c.

The insulating pattern IP may be disposed in the second non-emission area NEA2. The insulating pattern IP may be further disposed in the first-second emission area EA1b. In a plan view, the insulating pattern IP may be located inside the first-first emission area EA1a.

Although only one insulating pattern IP is illustrated in FIGS. 3 to 7, multiple insulating patterns IP may be disposed to correspond to the second non-emission areas NEA2 of the display area DA, respectively. Each of the insulating patterns IP may have an island pattern shape in a plan view.

The insulating pattern IP may include a flat portion IPa and an inclined portion IPb. The flat portion IPa of the insulating pattern IP may have a substantially flat upper surface. The inclined portion IPb of the insulating pattern IP may be located outside the flat portion IPa. An upper surface of the inclined portion IPb of the insulating pattern IP may be an inclined surface that is inclined with respect to each of the upper surface of the flat portion IPa and the upper surface of the circuit element layer CEL (e.g., the upper surface of the via insulating layer).

In an embodiment, a second inclination angle θ2, defined as an angle between the upper surface of the inclined portion IPb of the insulating pattern IP and the upper surface of the circuit element layer CEL (e.g., the upper surface of the via insulating layer), may be in a range of about 10 degrees to about 70 degrees. In an embodiment, the first inclination angle θ1 and the second inclination angle θ2 may be substantially the same.

In an embodiment, as illustrated in FIG. 5, in a plan view, the insulating layer IL may be spaced apart (i.e., may be spaced outward) from the insulating pattern IP and may surround the insulating pattern IP. The inclined portion ILb of the insulating layer IL may face the inclined portion IPb of a corresponding insulating pattern IP.

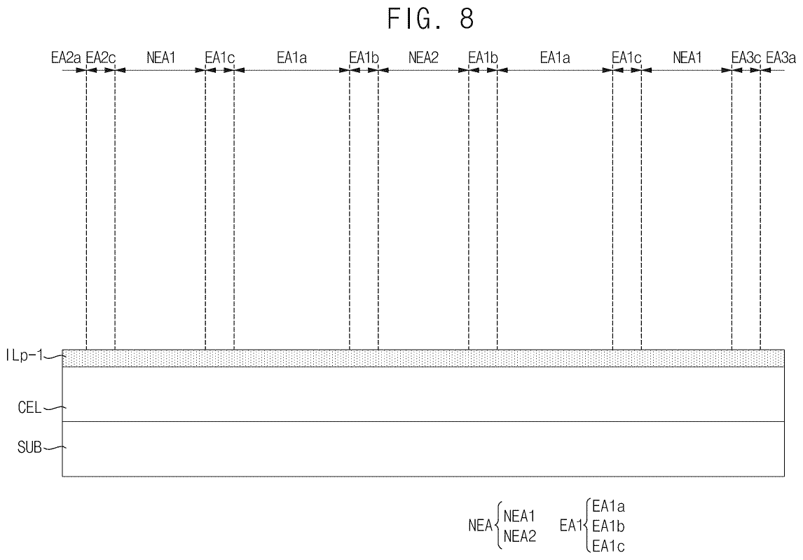

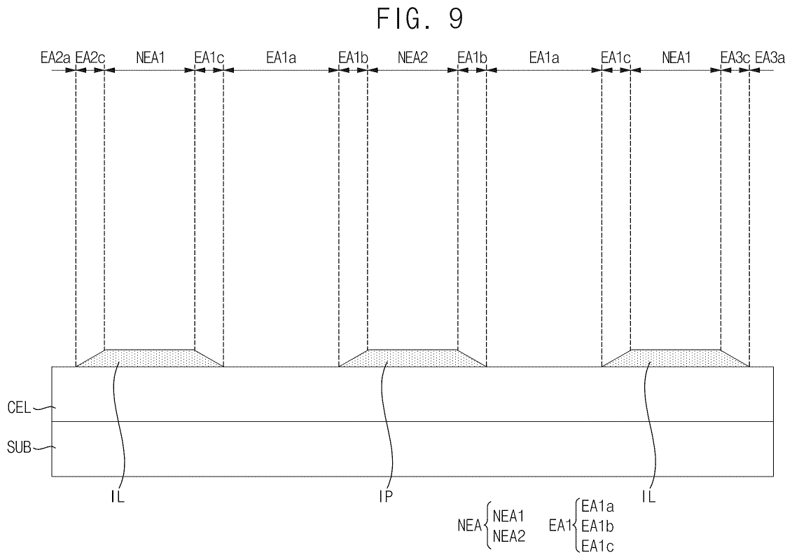

In an embodiment, the insulating layer IL and the insulating pattern IP may be disposed on substantially a same layer. The insulating layer IL and the insulating pattern IP may include a same material. The insulating layer IL and the insulating pattern IP may be substantially simultaneously formed (see FIGS. 8 and 9). For example, a level of the upper surface of the flat portion ILa of the insulating layer IL and a level of the upper surface of the flat portion IPa of the insulating pattern IP may be substantially the same.

In an embodiment, the insulating layer IL and the insulating pattern IP may include an organic material. For example, the insulating layer IL and the insulating pattern IP may include a photoresist, a polyacryl-based resin, a polyimide-based resin, a polyamide-based resin, a siloxane-based resin, an acrylic resin, an epoxy-based resin, or the like. In an embodiment, the insulating layer IL and the insulating pattern IP may further include a light blocking material. For example, the insulating layer IL and the insulating pattern IP may further include a black pigment such as carbon black or a black dye.

In another embodiment, the insulating layer IL and the insulating pattern IP may include an inorganic material. For example, the insulating layer IL and the insulating pattern IP may include silicon oxide (SiOₓ), silicon nitride (SiNₓ), silicon oxynitride (SiOₓN_{y}), or the like.

The first to third pixel electrodes PE1, PE2, and PE3 may be disposed on the circuit element layer CEL, the insulating layer IL, and the insulating pattern IP. The first to third pixel electrodes PE1, PE2, and PE3 may be disposed to correspond to the first to third emission areas EA1, EA2, and EA3, respectively. Hereinafter, the first pixel electrode PE1 disposed to correspond to the first emission area EA1 will be described in more detail.

The first pixel electrode PE1 may include a conductive material such as a metal, an alloy, a conductive metal nitride, a conductive metal oxide, a transparent conductive material, or the like. The first pixel electrode PE1 may have a single-layer structure or a multi-layer structure including multiple conductive layers.

The first pixel electrode PE1 may be disposed in an entire area of the first emission area EA1 and the second non-emission area NEA2. The first pixel electrode PE1 may be further disposed in a portion of the first non-emission area NEA1. In an embodiment, the first pixel electrode PE1 may have a substantially uniform thickness.

In an embodiment, the first pixel electrode PE1 may include first to fifth portions PE1a, PE1b, PE1c, PE1d, and PE1e. The first to fifth portions PE1a, PE1b, PE1c, PE1d, and PE1e of the first pixel electrode PE1 may be integrally (e.g., physically) connected to each other.

The first portion PE1a of the first pixel electrode PE1 may be a portion that is disposed on the flat portion IPa of the insulating pattern IP. For example, the flat portion IPa of the insulating pattern IP may be disposed between the circuit element layer CEL and the first portion PE1a of the first pixel electrode PE1. The first portion PE1a of the first pixel electrode PE1 may be disposed in the second non-emission area NEA2. For example, an upper surface of the first portion PE1a of the first pixel electrode PE1 may be substantially flat.

The upper surface of the first portion PE1a of the first pixel electrode PE1 may be covered by the pixel defining pattern PDP. The first portion PE1a of the first pixel electrode PE1 may be spaced apart from the intermediate layer ML including an emission layer with the pixel defining pattern PDP interposed between the first portion PE1a of the first pixel electrode PE1 and the intermediate layer ML. Accordingly, in an area overlapping the first portion PE1a of the first pixel electrode PE1, the emission layer may not emit light. The first portion PE1a of the first pixel electrode PE1 may be referred to as a central portion.

The second portion PE1b of the first pixel electrode PE1 may be a portion that is disposed on the flat portion ILa of the insulating layer IL. For example, the flat portion ILa of the insulating layer IL may be disposed between the circuit element layer CEL and the second portion PE1b of the first pixel electrode PE1 and between the circuit element layer CEL and the pixel defining layer PDL. The second portion PE1b of the first pixel electrode PE1 may be disposed in a portion of the first non-emission area NEA1. For example, an upper surface of the second portion PE1b of the first pixel electrode PE1 may be substantially flat.

As illustrated in FIG. 6, in a plan view, the second portion PE1b of the first pixel electrode PE1 may be located outside the first portion PE1a of the first pixel electrode PE1. In a plan view, the second portion PE1b of the first pixel electrode PE1 may be spaced apart from the first portion PE1a of the first pixel electrode PE1 and may surround the first portion PE1a of the first pixel electrode PE1.

The upper surface of the second portion PE1b of the first pixel electrode PE1 may be covered by the pixel defining layer PDL. The second portion PE1b of the first pixel electrode PE1 may be spaced apart from the intermediate layer ML including the emission layer with the pixel defining layer PDL interposed between the second portion PE1b of the first pixel electrode PE1 and the intermediate layer ML. Accordingly, in an area overlapping the second portion PE1b of the first pixel electrode PE1, the emission layer may not emit light. The second portion PE1b of the first pixel electrode PE1 may be referred to as an outer portion.

The third portion PE1c of the first pixel electrode PE1 may be a portion that is disposed on the circuit element layer CEL between the insulating layer IL and the insulating pattern IP. For example, the third portion PE1c of the first pixel electrode PE1 may be disposed on (e.g., directly disposed on) the upper surface of the circuit element layer CEL (e.g., the upper surface of the via insulating layer). The third portion PE1c of the first pixel electrode PE1 may be disposed in the first-first emission area EA1a. For example, an upper surface of the third portion PE1c of the first pixel electrode PE1 may be substantially flat. For example, a level of the upper surface of the third portion PE1c of the first pixel electrode PE1 may be lower than each of a level of the upper surface of the first portion PE1a of the first pixel electrode PE1 and a level of the upper surface of the second portion PE1b of the first pixel electrode PE1.

As illustrated in FIG. 6, in a plan view, the third portion PE1c of the first pixel electrode PE1 may be located between the first portion PE1a of the first pixel electrode PE1 and the second portion PE1b of the first pixel electrode PE1. For example, in a plan view, the third portion PE1c of the first pixel electrode PE1 may be located outside the first portion PE1a of the first pixel electrode PE1 and inside the second portion PE1b of the first pixel electrode PE1. In a plan view, the third portion PE1c of the first pixel electrode PE1 may be spaced apart from the first portion PE1a of the first pixel electrode PE1 and may surround the first portion PE1a of the first pixel electrode PE1.

The third portion PE1c of the first pixel electrode PE1 may contact the intermediate layer ML including the emission layer. Accordingly, in an area overlapping the third portion PE1c of the first pixel electrode PE1, the emission layer may emit light. The third portion PE1c of the first pixel electrode PE1 may be referred to as a first emission portion.

The fourth portion PE1d of the first pixel electrode PE1 may be a portion that is disposed on the inclined portion IPb of the insulating pattern IP. For example, the inclined portion IPb of the insulating pattern IP may be disposed between the circuit element layer CEL and the fourth portion PE1d of the first pixel electrode PE1. The fourth portion PE1d of the first pixel electrode PE1 may be disposed in the first-second emission area EA1b. For example, an upper surface of the fourth portion PE1d of the first pixel electrode PE1 may be inclined along the upper surface of the inclined portion IPb of the insulating pattern IP.

As illustrated in FIG. 6, in a plan view, the fourth portion PE1d of the first pixel electrode PE1 may be located between the first portion PE1a of the first pixel electrode PE1 and the third portion PE1c of the first pixel electrode PE1. For example, in a plan view, the fourth portion PE1d of the first pixel electrode PE1 may be located outside the first portion PE1a of the first pixel electrode PE1 and inside the third portion PE1c of the first pixel electrode PE1. In a plan view, the fourth portion PE1d of the first pixel electrode PE1 may surround the first portion PE1a of the first pixel electrode PE1, and the third portion PE1c of the first pixel electrode PE1 may surround the fourth portion PE1d of the first pixel electrode PE1.

The fourth portion PE1d of the first pixel electrode PE1 may contact the intermediate layer ML including the emission layer on the inclined portion IPb of the insulating pattern IP. Accordingly, in an area overlapping the fourth portion PE1d of the first pixel electrode PE1, the emission layer may emit light. The fourth portion PE1d of the first pixel electrode PE1 may be referred to as a second emission portion.

The fifth portion PE1e of the first pixel electrode PE1 may be a portion that is disposed on the inclined portion ILb of the insulating layer IL. For example, the inclined portion ILb of the insulating layer IL may be disposed between the circuit element layer CEL and the fifth portion PE1e of the first pixel electrode PE1. The fifth portion PE1e of the first pixel electrode PE1 may be disposed in the first-third emission area EA1c. For example, an upper surface of the fifth portion PE1e of the first pixel electrode PE1 may be inclined along the upper surface of the inclined portion ILb of the insulating layer IL.

As illustrated in FIG. 6, in a plan view, the fifth portion PE1e of the first pixel electrode PE1 may be located between the second portion PE1b of the first pixel electrode PE1 and the third portion PE1c of the first pixel electrode PE1. For example, in a plan view, the fifth portion PE1e of the first pixel electrode PE1 may be located outside the third portion PE1c of the first pixel electrode PE1 and inside the second portion PE1b of the first pixel electrode PE1. In a plan view, the fifth portion PE1e of the first pixel electrode PE1 may surround the third portion PE1c of the first pixel electrode PE1, and the second portion PE1b of the first pixel electrode PE1 may surround the fifth portion PE1e of the first pixel electrode PE1.

The fifth portion PE1e of the first pixel electrode PE1 may contact the intermediate layer ML including the emission layer on the inclined portion ILb of the insulating layer IL. Accordingly, in an area overlapping the fifth portion PE1e of the first pixel electrode PE1, the emission layer may emit light. The fifth portion PE1e of the first pixel electrode PE1 may be referred to as a third emission portion.

The pixel defining layer PDL may be disposed on the insulating layer IL and the first to third pixel electrodes PE1, PE2, and PE3.

The pixel defining layer PDL may be disposed in the first non-emission area NEA1. In a plan view, the pixel defining layer PDL may surround the first-third emission area EA1c. In an embodiment, the pixel defining layer PDL may have a grid shape in a plan view. In an embodiment, in a plan view, the pixel defining layer PDL may surround the first portion PE1a, the third portion PE1c, the fourth portion PE1d, and the fifth portion PE1e of the first pixel electrode PE1. In an embodiment, in a plan view, the pixel defining layer PDL may have a shape corresponding to a shape of the flat portion ILa of the insulating layer IL.

The pixel defining pattern PDP may be disposed on the insulating pattern IP and the first to third pixel electrodes PE1, PE2, and PE3. The pixel defining pattern PDP may be disposed on the first portion PE1a of the first pixel electrode PE1.

The pixel defining pattern PDP may be disposed in the second non-emission area NEA2. In a plan view, the pixel defining pattern PDP may be located inside the first-second emission area EA1b.

Although only one pixel defining pattern PDP is illustrated in FIGS. 3 to 7, multiple pixel defining patterns PDP may be disposed to correspond to the second non-emission areas NEA2 of the display area DA, respectively. Each of the pixel defining patterns PDP may have an island pattern shape in a plan view. In an embodiment, in a plan view, each of the pixel defining patterns PDP may have a shape corresponding to a shape of the flat portion IPa of the corresponding insulating pattern IP.

The pixel defining layer PDL may cover the second portion PE1b of the first pixel electrode PE1 on the insulating layer IL (e.g., on the flat portion ILa of the insulating layer IL). The second portion PE1b of the first pixel electrode PE1 and the intermediate layer ML may be spaced apart from each other by the pixel defining layer PDL.

The pixel defining pattern PDP may cover the first portion PE1a of the first pixel electrode PE1 on the insulating pattern IP (e.g., on the flat portion IPa of the insulating pattern IP). The first portion PE1a of the first pixel electrode PE1 and the intermediate layer ML may be spaced apart from each other by the pixel defining pattern PDP.

The pixel defining layer PDL and the pixel defining pattern PDP may not cover the third to fifth portions PE1c, PE1d, and PE1e of the first pixel electrode PE1. For example, the pixel defining layer PDL and the pixel defining pattern PDP may expose the third to fifth portions PE1c, PE1d, and PE1e of the first pixel electrode PE1. Accordingly, the third to fifth portions PE1c, PE1d, and PE1e of the first pixel electrode PE1 may contact the intermediate layer ML.

The first to third emission areas EA1, EA2, and EA3 and the non-emission area NEA may be defined by the pixel defining layer PDL and the pixel defining pattern PDP.

In an embodiment, as illustrated in FIG. 7, in a plan view, the pixel defining layer PDL may be spaced apart from the pixel defining pattern PDP and may surround the pixel defining pattern PDP.

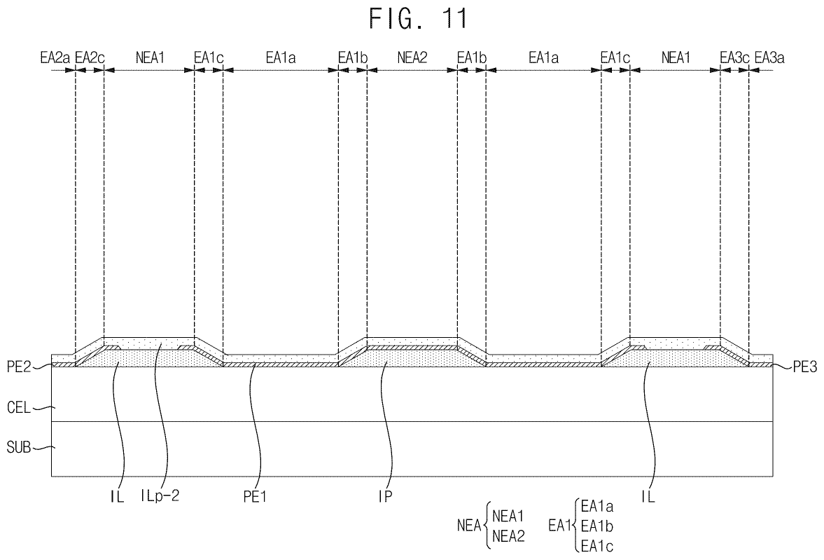

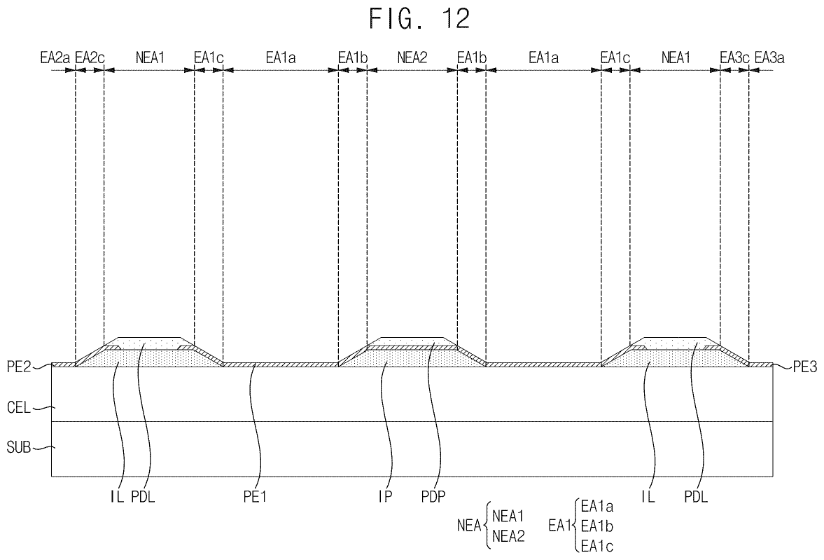

In an embodiment, the pixel defining layer PDL and the pixel defining pattern PDP may include a same material. The pixel defining layer PDL and the pixel defining pattern PDP may be substantially simultaneously formed (see FIGS. 11 and 12).

In an embodiment, the pixel defining layer PDL and the pixel defining pattern PDP may include an organic material. In an embodiment, the pixel defining layer PDL and the pixel defining pattern PDP may further include a light blocking material. For example, the pixel defining layer PDL and the pixel defining pattern PDP may further include a black pigment such as carbon black or a black dye. In another embodiment, the pixel defining layer PDL and the pixel defining pattern PDP may include an inorganic material.

In an embodiment, the pixel defining layer PDL, the pixel defining pattern PDP, the insulating layer IL, and the insulating pattern IP may include substantially a same material. In another embodiment, the pixel defining layer PDL and the pixel defining pattern PDP may include different material from the insulating layer IL and the insulating pattern IP.

The intermediate layer ML may be disposed on the first to third pixel electrodes PE1, PE2, and PE3, the pixel defining layer PDL, and the pixel defining pattern PDP. In an embodiment, the intermediate layer ML may include a first functional layer, the emission layer disposed on the first functional layer, and a second functional layer disposed on the emission layer.

In an embodiment, the first functional layer may include a hole transport layer (HTL), a hole injection layer (HIL), or both the hole transport layer and the hole injection layer.

In an embodiment, the emission layer may include an organic material, an inorganic material, or an organic-inorganic material that emits light of a certain color. For example, the emission layer may include an emission material that emits blue light, but the disclosure is not limited thereto.

In an embodiment, the second functional layer may include an electron transport layer (ETL), an electron injection layer (EIL), or both the electron transport layer and the electron injection layer.

In an embodiment, the intermediate layer ML may be disposed in an entire area of the display area DA. The intermediate layer ML may be disposed in an entire area of the first to third emission areas EA1, EA2, and EA3 and the non-emission area NEA. For example, each of the first functional layer, the emission layer, and the second functional layer may be disposed in an entire area of the first to third emission areas EA1, EA2, and EA3 and the non-emission area NEA.

The common electrode CE may be disposed on the intermediate layer ML. In an embodiment, the common electrode CE may be disposed in an entire area of the display area DA. The common electrode CE may be disposed in an entire area of the first to third emission areas EA1, EA2, and EA3 and the non-emission area NEA.

The common electrode CE may include a conductive material such as a metal, an alloy, a conductive metal nitride, a conductive metal oxide, a transparent conductive material, or the like. The common electrode CE may have a single-layer structure or a multi-layer structure including multiple conductive layers.

The encapsulation layer ENC may be disposed on the common electrode CE. The encapsulation layer ENC may include at least one inorganic encapsulation layer and at least one organic encapsulation layer. In an embodiment, the encapsulation layer ENC may include a first inorganic encapsulation layer disposed on the common electrode CE, an organic encapsulation layer disposed on the first inorganic encapsulation layer, and a second inorganic encapsulation layer disposed on the organic encapsulation layer.

The color conversion layer may be disposed on the encapsulation layer ENC. The color conversion layer may include a bank BNK, a first color conversion portion CCP1, a second color conversion portion CCP2, and a transmission portion TRP.

The bank BNK may be disposed in the display area DA on the encapsulation layer ENC. Multiple openings may be formed in the bank BNK. The bank BNK may provide spaces capable of accommodating an ink composition in a process of forming the first color conversion portion CCP1, the second color conversion portion CCP2, and the transmission portion TRP. For example, in a plan view, the bank BNK may be disposed in the first non-emission area NEA1 and may have a grid shape.

In an embodiment, the bank BNK may include an organic material. In an embodiment, the bank BNK may further include a light blocking material. For example, the bank BNK may further include a black pigment such as carbon black or a black dye.

The first color conversion portion CCP1, the second color conversion portion CCP2, and the transmission portion TRP may be disposed in the display area DA on the encapsulation layer ENC in the first to third emission areas EA1, EA2, and EA3, respectively. For example, the first color conversion portion CCP1, the second color conversion portion CCP2, and the transmission portion TRP may be disposed in the openings of the bank BNK, respectively.

The first color conversion portion CCP1 may be disposed in the first emission area EA1. In an embodiment, the first color conversion portion CCP1 may be further disposed in the second non-emission area NEA2 inside the first emission area EA1. The first color conversion portion CCP1 may overlap the first pixel electrode PE1 in a plan view.

The first color conversion portion CCP1 may convert blue incident light (e.g., light generated from the first light emitting element LED1 and incident into the first color conversion portion CCP1) into red light. For example, the first color conversion portion CCP1 may include a resin portion BR, a scattering particle SC, and a first color conversion particle CC1.

The scattering particle SC may increase an optical path by scattering the incident light without substantially changing the wavelength of the incident light incident on the first color conversion portion CCP1. The scattering particle SC may include a metal oxide or an organic material. In another embodiment, the scattering particle SC may be omitted.

In an embodiment, the first color conversion particle CC1 may include a quantum dot. The quantum dot may include a semiconductor material forming nanocrystals. The quantum dot may have a specific band gap depending on its composition and size. Accordingly, the quantum dots may absorb the incident light and emit light having a different wavelength from a wavelength of the incident light. For example, the quantum dot may have a diameter less than or equal to about 100 nanometers. For example, the quantum dot may have a diameter in a range of about 1 nanometer to about 20 nanometers. For example, the first color conversion particle CCI of the first color conversion portion CCP1 may include a quantum dot that absorbs blue light and emits red light.

The scattering particle SC and the first color conversion particle CC1 may be located in the resin portion BR. For example, the resin portion BR may include an epoxy-based resin, an acrylic-based resin, a phenol-based resin, a melamine-based resin, a cardo-based resin, an imide-based resin, or the like, but the disclosure is not limited thereto.

The first color conversion portion CCP1 may convert the blue incident light to red light.

The second color conversion portion CCP2 may be disposed in the second emission area EA2. In an embodiment, the second color conversion portion CCP2 may be further disposed in the second non-emission area NEA2 inside the second emission area EA2. The second color conversion portion CCP2 may overlap the second pixel electrode PE2 in a plan view.

The second color conversion portion CCP2 may convert blue incident light (e.g., light generated from the second light emitting element LED2 and incident into the second color conversion portion CCP2) into green light. For example, the second color conversion portion CCP2 may include a resin portion BR, a scattering particle SC, and a second color conversion particle CC2.

In an embodiment, the second color conversion particle CC2 may include a quantum dot that absorbs blue light and emits green light. Therefore, the second color conversion portion CCP2 may convert the blue incident light to green light.

The transmission portion TRP may be disposed in the third emission area EA3. In an embodiment, although not illustrated in the drawing, the transmission portion TRP may be further disposed in the second non-emission area NEA2 inside the third emission area EA3. The transmission portion TRP may overlap the third pixel electrode PE3 in a plan view. For example, the transmission portion TRP may include a resin portion BR and a scattering particle SC.

The transmission portion TRP may not convert blue incident light (e.g., light generated from the third light emitting element LED3 and incident into the transmission portion TRP). For example, the transmission portion TRP may emit light having a substantially same wavelength as a wavelength of the incident light. Therefore, blue light may be emitted to the outside in the third emission area EA3.

The first protective layer PL1 may cover the first color conversion portion CCP1, the second color conversion portion CCP2, and the transmission portion TRP. The first protective layer PL1 may include an organic insulating material or an inorganic insulating material.

The color filter layer may be disposed on the first protective layer PL1. The color filter layer may include a first color filter CF1, a second color filter CF2, a third color filter CF3, a light blocking layer LBL, and a light blocking pattern LBP.

The first color filter CF1 may be disposed in the first emission area EA1. In an embodiment, the first color filter CF1 may be further disposed in the second non-emission area NEA2 inside the first emission area EA1. The first color filter CF1 may not be disposed in the second and third emission areas EA2 and EA3. The first color filter CF1 may overlap the first pixel electrode PE1 in a plan view.

In an embodiment, the first color filter CF1 may be a red color filter that selectively transmits red light. For example, the first color filter CF1 may include an organic material such as a photoresist and may further include a red pigment or a red dye. Blue light that is not converted by the first color conversion portion CCP1 may be blocked by the first color filter CF1. Therefore, red light may be emitted to the outside from the first emission area EA1.

The second color filter CF2 may be disposed in the second emission area EA2. In an embodiment, the second color filter CF2 may be further disposed in the second non-emission area NEA2 inside the second emission area EA2. The second color filter CF2 may not be disposed in the first and third emission areas EA1 and EA3. The second color filter CF2 may overlap the second pixel electrode PE2 in a plan view.

In an embodiment, the second color filter CF2 may be a green color filter that selectively transmits green light. For example, the second color filter CF2 may include an organic material such as a photoresist and may further include a green pigment or a green dye. Blue light that is not converted by the second color conversion portion CCP2 may be blocked by the second color filter CF2. Therefore, green light may be emitted to the outside from the second emission area EA2.

The third color filter CF3 may be disposed in the third emission area EA3. In an embodiment, the third color filter CF3 may be further disposed in the second non-emission area NEA2 inside the third emission area EA3. The third color filter CF3 may not be disposed in the first and second emission areas EA1 and EA2. The third color filter CF3 may overlap the third pixel electrode PE3 in a plan view.

In an embodiment, the third color filter CF3 may be a blue color filter that selectively transmits blue light. For example, the third color filter CF3 may include an organic material such as a photoresist and may further include a blue pigment or a blue dye.

The light blocking layer LBL may be disposed in the first non-emission area NEA1. The light blocking layer LBL may be disposed between the first to third color filters CF1, CF2, and CF3 adjacent to each other. In an embodiment, the light blocking layer LBL may have a grid shape in a plan view. The light blocking layer LBL may prevent or reduce color mixing between the first to third emission areas EA1, EA2, and EA3 adjacent to each other.

The light blocking pattern LBP may be disposed in the second non-emission area NEA2. In a plan view, the light blocking pattern LBP may be located inside the first-second emission area EA1b. The light blocking pattern LBP may reduce light incident from the outside from being re-emitted to the outside by reflecting inside the display device DD.

Although only one light blocking pattern LBP is illustrated in FIG. 3, multiple pixel light blocking patterns LBP may be disposed to correspond to the second non-emission areas NEA2 of the display area DA, respectively. Each of the light blocking patterns LBP may have an island pattern shape in a plan view.

In an embodiment, each of the light blocking layer LBL and the light blocking pattern LBP may include an organic material such as a photoresist and may further include a black pigment or a black dye.

In another embodiment, unlike illustrated in the drawing, each of the light blocking layer LBL and the light blocking pattern LBP may be formed by stacking the first to third color filters CF1, CF2, and CF3 in a thickness direction.

The second protective layer PL2 may cover the first to third color filters CF1, CF2, and CF3. The second protective layer PL2 may include an organic insulating material or an inorganic insulating material.

In one embodiment, although not illustrated in the drawing, the display device DD may further include various functional layers (e.g., a touch sensing layer, a light collecting layer, or the like) disposed on the encapsulating layer ENC.

According to embodiments, each of the unit pixel areas UPA included in the display area DA of the display device DD may include first to third emission areas EA1, EA2, and EA3 that emit light of different colors. Each of the first to third emission areas EA1, EA2, and EA3 may have a ring shape in a plan view. The light blocking pattern LBP may be disposed in the second non-emission area NEA2 that is located inside each of the first to third emission areas EA1, EA2, and EA3. The light blocking pattern LBP may reduce light incident from the outside from being re-emitted to the outside by reflecting inside the display device DD. Accordingly, a display quality of the display device DD may be improved.

In an embodiment, the first pixel electrode PE1 may include the first emission portion PE1c, the second emission portion PE1d, and the third emission portion PE1e that each contact the intermediate layer ML including the emission layer. The first emission portion PE1c may have a flat upper surface, and each of the second emission portion PE1d and the third emission portion PE1e may have an inclined upper surface. In an area overlapping the first to third emission portions PE1c, PE1d, and PE1e of the first pixel electrode PE1, the emission layer may emit light. Therefore, an emission area of the emission layer may increase, thus, a brightness of the display device DD may be improved. Since light is emitted also from an inclined portion of the emission layer (e.g., a portion, which is on the second and third emission portions PE1d and PE1e of the first pixel electrode PE1, of the emission layer), compared to a case where light is emitted only from a flat portion of the emission layer (e.g., a portion, which is on the first emission portion PE1c of the first pixel electrode PE1, of the emission layer), a length of a path through which light emitted from the first light emitting element LED1 passes through the first color conversion portion CCP1 may be increased. Accordingly, an excitation efficiency of light by the first color conversion particle CC1 in the first color conversion portion CCP1 may be improved, thus, the brightness of the display device DD may be further improved. Therefore, the display quality of the display device DD may be further improved.

FIGS. 8 to 13 are schematic cross-sectional views illustrating a method of manufacturing the display device of FIG. 3.

Referring to FIGS. 8 to 13, an embodiment of a method of manufacturing the display device DD of FIG. 3 will be described. Hereinafter, descriptions overlapping the descriptions of the display device DD described above with reference to FIGS. 2 to 7 will be omitted or simplified.

Referring to FIG. 8, the circuit element layer CEL may be formed on the substrate SUB. A first preliminary insulating layer ILp-1 may be formed on the circuit element layer CEL. In an embodiment, the first preliminary insulating layer ILp-1 may include an organic material. The first preliminary insulating layer ILp-1 may further include a light blocking material.

In an embodiment, the first preliminary insulating layer ILp-1 may be formed in an entire area of the first to third emitting areas EA1, EA2, and EA3 and the non-emission area NEA.

Referring to FIG. 9, the insulating layer IL and the insulating pattern IP spaced apart from each other may be formed by patterning the first preliminary insulating layer ILp-1. In an embodiment, the first preliminary insulating layer ILp-1 may include a photoresist, and the insulating layer IL and the insulating pattern IP may be formed by exposing and developing the first preliminary insulating layer ILp-1 using a photomask. In another embodiment, a photoresist pattern may be formed on the first preliminary insulating layer ILp-1, and the insulating layer IL and the insulating pattern IP may be formed by partially etching the first preliminary insulating layer ILp-1 using the photoresist pattern as an etching mask.

In an embodiment, by adjusting process conditions of the patterning process of the first preliminary insulating layer ILp-1, the first inclination angle θ1 of the inclined portion ILb of the insulating layer IL and the second inclination angle θ2 of the inclined portion IPb of the insulating pattern IP of FIG. 4 may be appropriately adjusted.

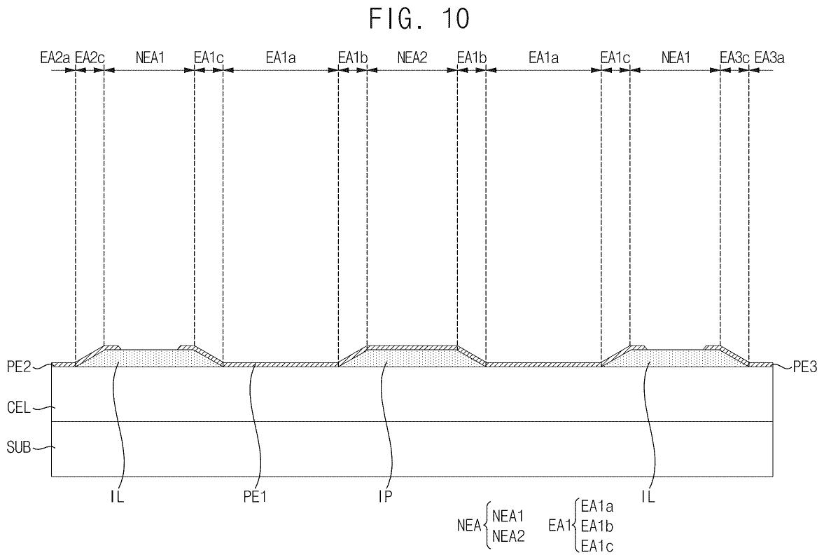

Referring to FIG. 10, the first to third pixel electrodes PE1, PE2, and PE3 spaced apart from each other may be formed on the circuit element layer CEL, the insulating layer IL, and the insulating pattern IP.

In an embodiment, a preliminary conductive layer may be entirely formed on the circuit element layer CEL, the insulating layer IL, and the insulating pattern IP. A photoresist pattern may be formed on the preliminary conductive layer, and the first to third pixel electrodes PE1, PE2, and PE3 may be formed by partially etching the preliminary conductive layer using the photoresist pattern as an etching mask.

Referring to FIG. 11, a second preliminary insulating layer ILp-2 may be formed on the insulating layer IL and the first to third pixel electrodes PE1, PE2, and PE3. In an embodiment, the second preliminary insulating layer ILp-2 may include an organic material. The second preliminary insulating layer ILp-2 may further include a light blocking material. In an embodiment, the second preliminary insulating layer ILp-2, and the first preliminary insulating layer ILp-1 may include a same material.

In an embodiment, the second preliminary insulating layer ILp-2 may be formed in an entire area of the first to third emitting areas EA1, EA2, and EA3 and the non-emission area NEA.

Referring to FIG. 12, the pixel defining layer PDL and the pixel defining pattern PDP spaced apart from each other may be formed by patterning the second preliminary insulating layer ILp-2. In an embodiment, the second preliminary insulating layer ILp-2 may include a photoresist, and the pixel defining layer PDL and the pixel defining pattern PDP may be formed by exposing and developing the second preliminary insulating layer ILp-2 using a photomask. In another embodiment, a photoresist pattern may be formed on the second preliminary insulating layer ILp-2, and the pixel defining layer PDL and the pixel defining pattern PDP may be formed by partially etching the second preliminary insulating layer ILp-2 using the photoresist pattern as an etching mask.

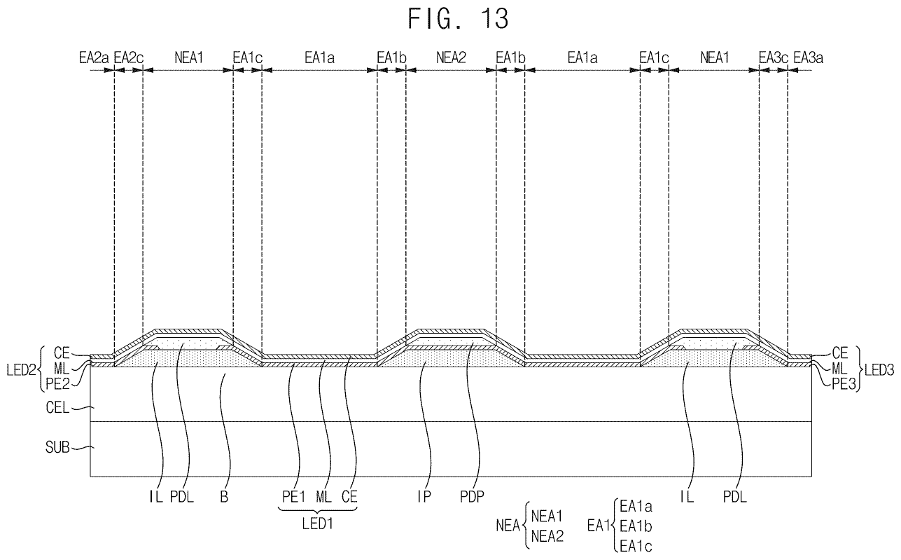

Referring to FIG. 13, the intermediate layer ML including an emission layer and the common electrode CE may be sequentially formed on the first to third pixel electrodes PE1, PE2, and PE3, the pixel defining layer PDL, and the pixel defining pattern PDP. In an embodiment, each of the intermediate layer ML and the common electrode CE may be formed in an entire area of the first to third emission areas EA1, EA2, and EA3 and the non-emission area NEA.

The encapsulation layer ENC, the color conversion layer, the first protective layer PL1, the color filter layer, and the second protective layer PL2 illustrated in FIG. 3 may be sequentially formed to manufacture the display device DD.

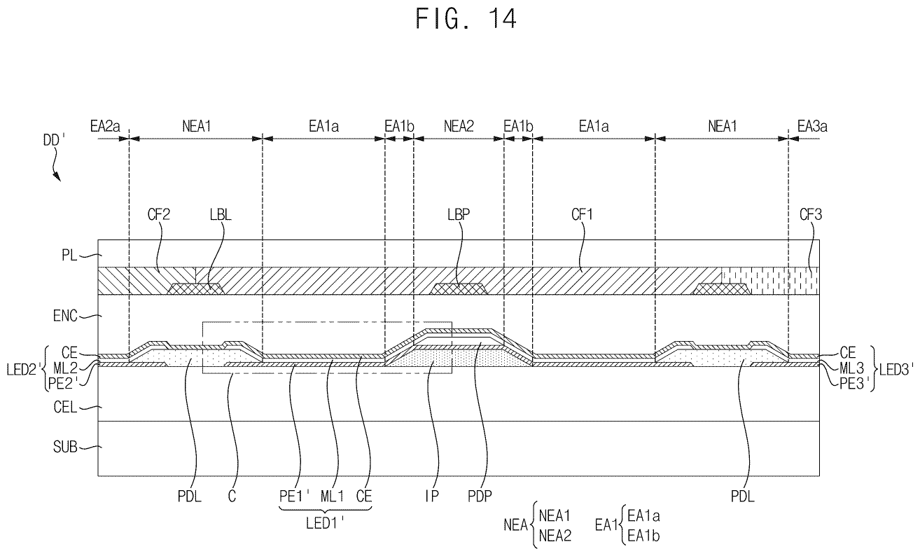

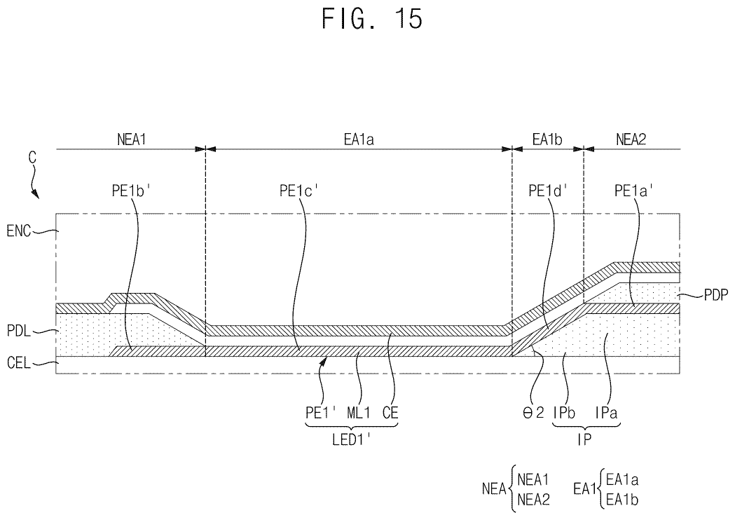

FIG. 14 is a schematic cross-sectional view illustrating a display device according to an embodiment. FIG. 15 is an enlarged schematic cross-sectional view illustrating area C of FIG. 14.

The FIG. 14 may correspond to the FIG. 3.

Hereinafter, a display device DD′ according to an embodiment will be described focusing on differences from the display device DD described above with reference to FIGS. 2 to 7, and repeated description will be omitted or simplified.

Referring to FIG. 14, in an embodiment, the display device DD′ may include a display area and a non-display area. The display area may include multiple unit pixel areas. Each of the unit pixel areas may include first to third emission areas EA1, EA2, and EA3 and a non-emission area NEA. The non-emission area NEA may include a first non-emission area NEA1 and multiple second non-emission areas NEA2.

First to third light emitting elements LED1′, LED2′, and LED3′ may be disposed in the first to third emission areas EA1, EA2, and EA3, respectively. The first to third emission areas EA1, EA2, and EA3 may emit light of different colors. For example, the first emission area EA1 may emit red light, the second emission area EA2 may emit green light, and the third emission area EA3 may emit blue light.

The first to third light emitting elements LED1′, LED2′, and LED3′ may emit light of different colors. For example, the first light emitting element LED1′ may emit red light, the second light emitting element LED2′ may emit green light, and the third light emitting element LED3′ may emit blue light.

In an embodiment, the first emission area EA1 may include a first-first emission area EA1a and a first-second emission area EA1b. In a plan view, the first-second emission area EA1b may surround a corresponding second non-emission area NEA2, and the first-first emission area EA1a may surround the first-second emission area EA1b. Each of the second and third emission areas EA2 and EA3 may have a structure similar to the first emission area EA1.

Referring to FIGS. 14 and 15, the display device DD′ may include a substrate SUB, a circuit element layer CEL, an insulating pattern IP, first to third pixel electrodes PE1′, PE2′, and PE3′, a pixel defining layer PDL, a pixel defining pattern PDP, first to third intermediate layers ML1, ML2, and ML3, a common electrode CE, an encapsulation layer ENC, a color filter layer, and a protective layer PL. The first pixel electrode PE1′, the first intermediate layer ML1, and the common electrode CE may form the first light emitting element LED1″. The second pixel electrode PE2′, the second intermediate layer ML2, and the common electrode CE may form the second light emitting element LED2′. The third pixel electrode PE3′, the third intermediate layer ML3, and the common electrode CE may form the third light emitting element LED3′. In the embodiment, the insulating layer IL and the color conversion layer of FIG. 4 may be omitted.

The insulating pattern IP may be disposed in the second non-emission area NEA2. The insulating pattern IP may be further disposed in the first-second emission area EA1b. In a plan view, the insulating pattern IP may be located inside the first-first emission area EA1a.

The insulating pattern IP may include a flat portion IPa and an inclined portion IPb. The flat portion IPa of the insulating pattern IP may have a substantially flat upper surface. The inclined portion IPb of the insulating pattern IP may be located outside the flat portion IPa. An upper surface of the inclined portion IPb of the insulating pattern IP may be an inclined surface that is inclined with respect to each of the upper surface of the flat portion IPa and the upper surface of the circuit element layer CEL (e.g., an upper surface of a via insulating layer).

In an embodiment, an inclination angle θ2, defined as an angle between the upper surface of the inclined portion IPb of the insulating pattern IP and the upper surface of the circuit element layer CEL (e.g., the upper surface of the via insulating layer), may be in a range of about 10 degrees to about 70 degrees.

In an embodiment, the insulating pattern IP may include an organic material. The insulating pattern IP may further include a light blocking material. In another embodiment, the insulating pattern IP may include an inorganic material.

The first to third pixel electrodes PE1′, PE2′, and PE3′ may be disposed on the circuit element layer CEL and the insulating pattern IP. The first to third pixel electrodes PE1′, PE2′, and PE3′ may be disposed to correspond to the first to third emission areas EA1, EA2, and EA3, respectively. Hereinafter, the first pixel electrode PE1′ disposed to correspond to the first emission area EA1 will be described in more detail.

The first pixel electrode PE1′ may be disposed in an entire area of the first emission area EA1 and the second non-emission area NEA2. The first pixel electrode PE1′ may be further disposed in a portion of the first non-emission area NEA1. In an embodiment, the first pixel electrode PE1′ may have a substantially uniform thickness.

In an embodiment, the first pixel electrode PE1′ may include first to fourth portions PE1a′, PE1b′, PE1c′, and PE1d′. The first to fourth portions PE1a′, PE1b′, PE1c′, and PE1d of the first pixel electrode PE1′ may be integrally (e.g., physically) connected to each other.

The first portion PE1a′ of the first pixel electrode PE1′ may be a portion that is disposed on the flat portion IPa of the insulating pattern IP. For example, the flat portion IPa of the insulating pattern IP may be disposed between the circuit element layer CEL and the first portion PE1a′ of the first pixel electrode PE1′. The first portion PE1a′ of the first pixel electrode PE1′ may be disposed in the second non-emission area NEA2. For example, an upper surface of the first portion PE1a′ of the first pixel electrode PE1′ may be substantially flat.

The upper surface of the first portion PE1a′ of the first pixel electrode PE1′ may be covered by the pixel defining pattern PDP. The first portion PE1a′ of the first pixel electrode PE1′ may be spaced apart from the first intermediate layer ML1 including a first emission layer with the pixel defining pattern PDP interposed between the first portion PE1a′ of the first pixel electrode PE1′ and the first intermediate layer ML1. Accordingly, in an area overlapping the first portion PE1a′ of the first pixel electrode PE1′, the first emission layer may not emit light. The first portion PE1a′ of the first pixel electrode PE1′ may be referred to as a central portion.

The second portion PE1b′ of the first pixel electrode PE1′ may be disposed between the circuit element layer CEL and the pixel defining layer PDL. The second portion PE1b′ of the first pixel electrode PE1′ may be disposed in a portion of the first non-emission area NEA1. For example, an upper surface of the second portion PE1b′ of the first pixel electrode PE1′ may be substantially flat.

The upper surface of the second portion PE1b′ of the first pixel electrode PE1′ may be covered by the pixel defining layer PDL. The second portion PE1b′ of the first pixel electrode PE1′ may be spaced apart from the first intermediate layer ML1 including the first emission layer with the pixel defining layer PDL interposed between the second portion PE1b′ of the first pixel electrode PE1′ and the first intermediate layer ML1. Accordingly, in an area overlapping the second portion PE1b′ of the first pixel electrode PE1′, the first emission layer may not emit light. The second portion PE1b′ of the first pixel electrode PE1 may be referred to as an outer portion.

The third portion PE1c′ of the first pixel electrode PE1′ may be disposed on (e.g., directly disposed on) the upper surface of the circuit element layer CEL (e.g., the upper surface of the via insulating layer). The third portion PE1c′ of the first pixel electrode PE1′ may be disposed in the first-first emission area EA1a. For example, an upper surface of the third portion PE1c′ of the first pixel electrode PE1′ may be substantially flat. For example, a level of the upper surface of the third portion PE1c′ of the first pixel electrode PE1′ may be lower than a level of the upper surface of the first portion PE1a′ of the first pixel electrode PET.

The third portion PE1c′ of the first pixel electrode PE1′ may contact the first intermediate layer ML1 including the first emission layer. Accordingly, in an area overlapping the third portion PE1c′ of the first pixel electrode PE1′, the first emission layer may emit light. The third portion PE1c′ of the first pixel electrode PE1′ may be referred to as a first emission portion.

The fourth portion PE1d of the first pixel electrode PE1′ may be a portion that is disposed on the inclined portion IPb of the insulating pattern IP. For example, the inclined portion IPb of the insulating pattern IP may be disposed between the circuit element layer CEL and the fourth portion PE1d′ of the first pixel electrode PE1′. The fourth portion PE1d′ of the first pixel electrode PE1′ may be disposed in the first-second emission area EA1b. For example, an upper surface of the fourth portion PE1d′ of the first pixel electrode PE1′ may be inclined along the upper surface of the inclined portion IPb of the insulating pattern IP.

The fourth portion PE1d′ of the first pixel electrode PE1′ may contact the first intermediate layer ML1 including the first emission layer on the inclined portion IPb of the insulating pattern IP. Accordingly, in an area overlapping the fourth portion PE1d′ of the first pixel electrode PE1′, the first emission layer may emit light. The fourth portion PE1d′ of the first pixel electrode PE1′ may be referred to as a second emission portion.

The pixel defining layer PDL may be disposed on the circuit element layer CEL and the first to third pixel electrodes PE1′, PE2′, and PE3′.

The pixel defining layer PDL may be disposed in the first non-emission area NEA1. In a plan view, the pixel defining layer PDL may surround the first-first emission area EA1a. In an embodiment, the pixel defining layer PDL may have a grid shape in a plan view. In an embodiment, in a plan view, the pixel defining layer PDL may surround the first portion PE1a′, the third portion PE1c′, and the fourth portion PE1d′ of the first pixel electrode PE1.

The pixel defining pattern PDP may be disposed on the insulating pattern IP and the first to third pixel electrodes PE1′, PE2′, and PE3′. The pixel defining pattern PDP may be disposed on the first portion PE1a′ of the first pixel electrode PE1′.

The pixel defining pattern PDP may be disposed in the second non-emission area NEA2. In a plan view, the pixel defining pattern PDP may be located inside the first-second emission area EA1b.

The pixel defining layer PDL may cover the second portion PE1b′ of the first pixel electrode PE1′ on the circuit element layer CEL. The second portion PE1b′ of the first pixel electrode PE1′ and the first intermediate layer ML1 may be spaced apart from each other by the pixel defining layer PDL.

The pixel defining pattern PDP may cover the first portion PE1a′ of the first pixel electrode PE1′ on the insulating pattern IP (e.g., on the flat portion IPa of the insulating pattern IP). The first portion PE1a′ of the first pixel electrode PE1′ and the first intermediate layer ML1 may be spaced apart from each other by the pixel defining pattern PDP.

The pixel defining layer PDL and the pixel defining pattern PDP may not cover the third and fourth portions PE1c′ and PE1d′ of the first pixel electrode PE1′. For example, the pixel defining layer PDL and the pixel defining pattern PDP may expose the third and fourth portions PE1c′ and PE1d′ of the first pixel electrode PE1′. Accordingly, the third and fourth portions PE1c′ and PE1d′ of the first pixel electrode PE1′ may contact the first intermediate layer ML1.

The first to third emission areas EA1, EA2, and EA3 and the non-emission area NEA may be defined by the pixel defining layer PDL and the pixel defining pattern PDP.

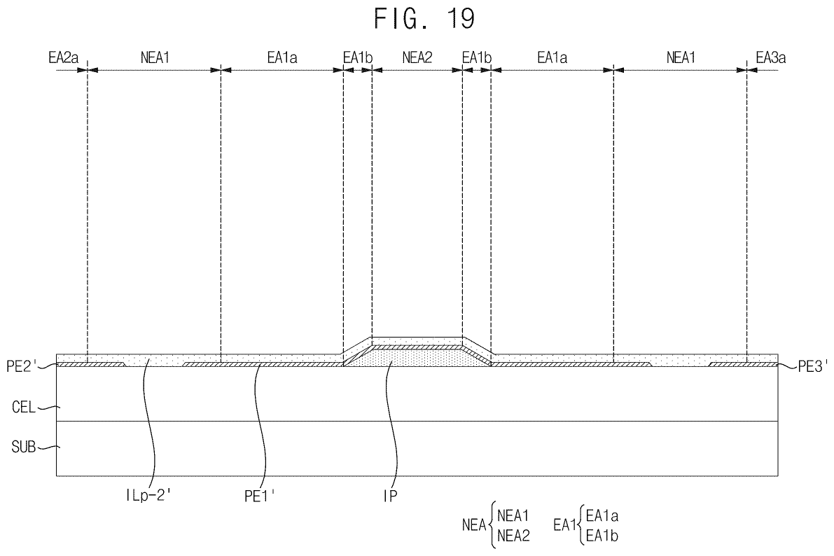

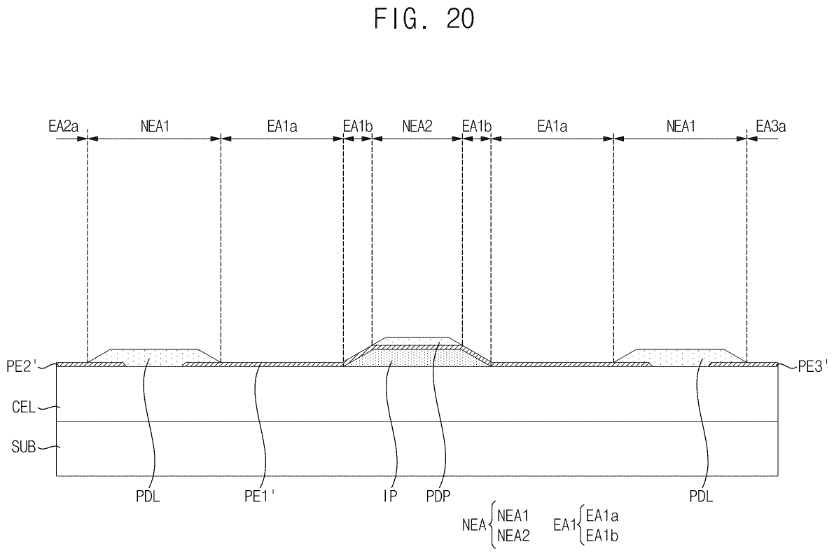

In an embodiment, the pixel defining layer PDL and the pixel defining pattern PDP may include a same material. The pixel defining layer PDL and the pixel defining pattern PDP may be substantially simultaneously formed (see FIGS. 19 and 20).

In another embodiment, the pixel defining layer PDL and the insulating pattern IP may include a same material. The pixel defining layer PDL may be substantially simultaneously formed with the insulating pattern IP.

The first to third intermediate layers ML1, ML2, and ML3 may be disposed on the first to third pixel electrodes PE1′, PE2′, and PE3′, the pixel defining layer PDL, and the pixel defining pattern PDP. In an embodiment, the first intermediate layer ML1 may include a first-first functional layer, the first emission layer disposed on the first-first functional layer, and a first-second functional layer disposed on the first emission layer. The second intermediate layer ML2 may include a second-first functional layer, the second emission layer disposed on the second-first functional layer, and a second-second functional layer disposed on the second emission layer. The third intermediate layer ML3 may include a third-first functional layer, the third emission layer disposed on the third-first functional layer, and a third-second functional layer disposed on the third emission layer.

The first to third emission layers may be disposed to respectively correspond to the first to third emission areas EA1, EA2, and EA3, and may be spaced apart from each other. For example, the first emission layer may include an emission material that emits red light, the second emission layer may include an emission material that emits green light, and the third emission layer may include an emission material that emits blue light.

In an embodiment, the first to third emission layers may be formed only in areas corresponding to the first to third emission areas EA1, EA2, and EA3, respectively, using a deposition mask (e.g., a fine metal mask (FMM)), and a support portion of the deposition mask may be disposed on an upper surface of the pixel defining layer PDL. As illustrated in FIG. 3, if the insulating layer IL is located under the pixel defining layer PDL, an area of the upper surface of the pixel defining layer PDL may be reduced, thereby reducing a space in which the support portion of the deposition mask is disposed. Therefore, in the display device DD′ according to an embodiment of FIG. 14, the insulating layer IL of FIG. 3 may be omitted.

Although FIG. 14 illustrates that the first to third intermediate layers ML1, ML2, and ML3 are spaced apart from each other, in an embodiment, the first-first functional layer, the second-first functional layer, and the third-first functional layer may be integrally formed, and the first-second functional layer, the second-second functional layer, and the third-second functional layer may be integrally formed.

The common electrode CE may be disposed on the first to third intermediate layers ML1, ML2, and ML3. In an embodiment, the common electrode CE may be disposed in an entire area of the first to third emission areas EA1, EA2, and EA3 and the non-emission area NEA.

The encapsulation layer ENC may be disposed on the common electrode CE. The color filter layer may be disposed on the encapsulation layer ENC. The color filter layer may include a first color filter CF1, a second color filter CF2, a third color filter CF3, a light blocking layer LBL, and a light blocking pattern LBP. The color filter layer may prevent or reduce color mixing between the first to third emission areas EA1, EA2, and EA3 adjacent to each other.

The protective layer PL may cover the first to third color filters CF1, CF2, and CF3. The protective layer PL may include an organic insulating material or an inorganic insulating material.

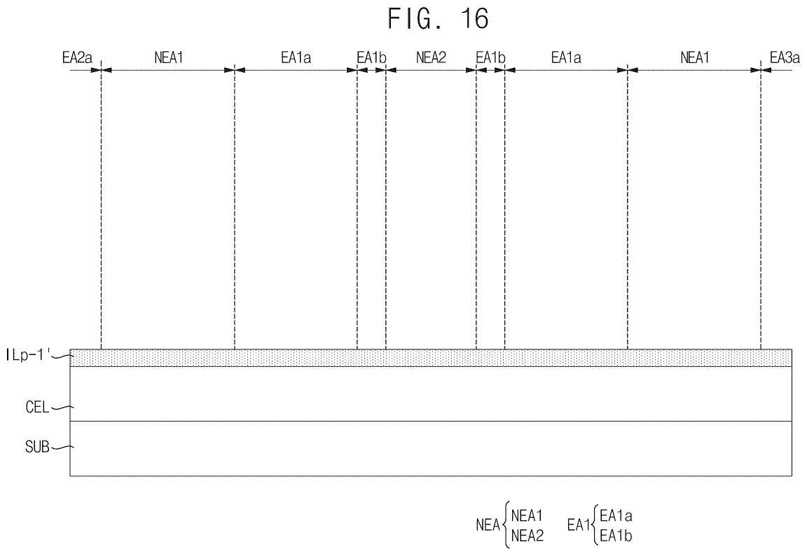

FIGS. 16 to 21 are schematic cross-sectional views illustrating a method of manufacturing the display device of FIG. 14.

Referring to FIGS. 16 to 21, an embodiment of a method of manufacturing the display device DD′ of FIG. 14 will be described. Hereinafter, descriptions overlapping the descriptions of the display device DD′ described above with reference to FIGS. 14 and 15 will be omitted or simplified.

Referring to FIG. 16, the circuit element layer CEL may be formed on the substrate SUB. A first preliminary insulating layer ILp-1′ may be formed on the circuit element layer CEL. In an embodiment, the first preliminary insulating layer ILp-1′ may include an organic material. The first preliminary insulating layer ILp-1′ may further include a light blocking material.

In an embodiment, the first preliminary insulating layer ILp-1′ may be formed in an entire area of the first to third emitting areas EA1, EA2, and EA3 and the non-emission area NEA.

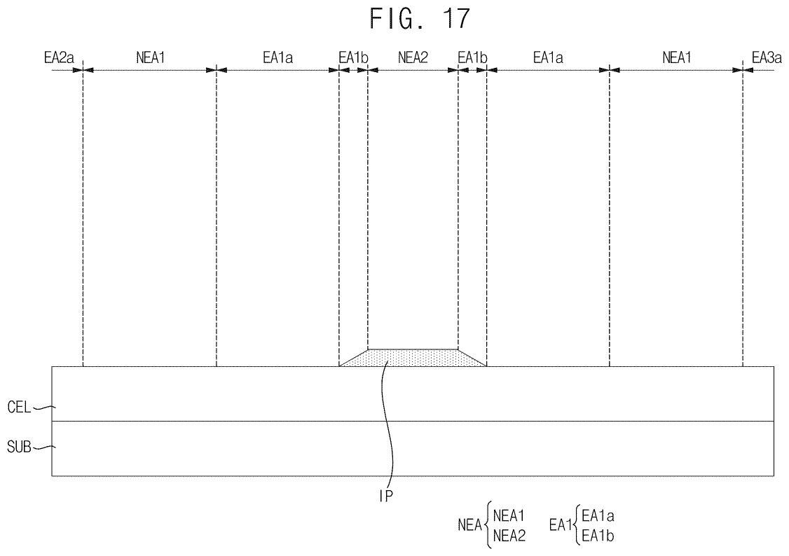

Referring to FIG. 17, the insulating pattern IP may be formed by patterning the first preliminary insulating layer ILp-1′. In an embodiment, the first preliminary insulating layer ILp-1′ may include a photoresist, and the insulating pattern IP may be formed by exposing and developing the first preliminary insulating layer ILp-1′ using a photomask. In another embodiment, a photoresist pattern may be formed on the first preliminary insulating layer ILp-1′, and the insulating pattern IP may be formed by partially etching the first preliminary insulating layer ILp-1′ using the photoresist pattern as an etching mask.

In an embodiment, by adjusting process conditions of the patterning process of the first preliminary insulating layer ILp-1′, the inclination angle θ2 of the inclined portion IPb of the insulating pattern IP of FIG. 15 may be appropriately adjusted.

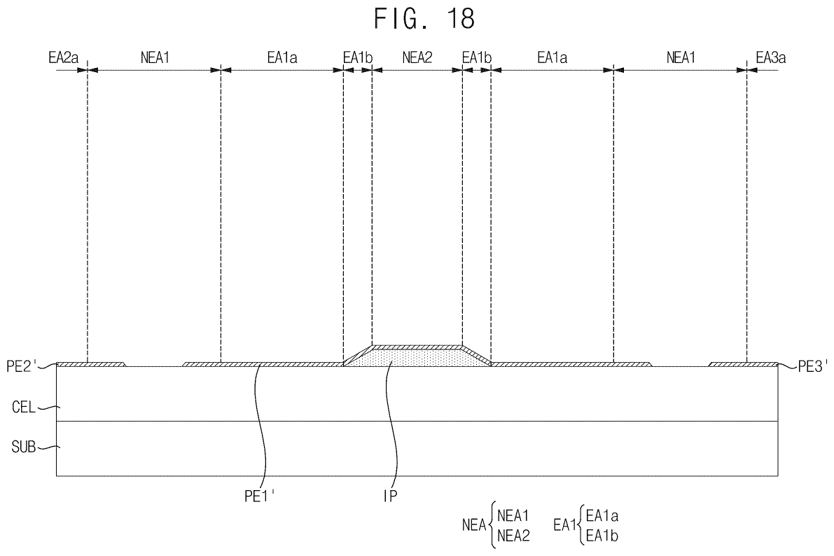

Referring to FIG. 18, the first to third pixel electrodes PE1′, PE2′, and PE3′ spaced apart from each other may be formed on the circuit element layer CEL and the insulating pattern IP.

In an embodiment, a preliminary conductive layer may be formed on an entire area of the circuit element layer CEL and the insulating pattern IP. A photoresist pattern may be formed on the preliminary conductive layer, and the first to third pixel electrodes PE1′, PE2′, and PE3′ may be formed by partially etching the preliminary conductive layer using the photoresist pattern as an etching mask.

Referring to FIG. 19, a second preliminary insulating layer ILp-2′ may be formed on the circuit element layer CEL and the first to third pixel electrodes PE1′, PE2′, and PE3′. In an embodiment, the second preliminary insulating layer ILp-2′ may include an organic material. The second preliminary insulating layer ILp-2′ may further include a light blocking material. In an embodiment, the second preliminary insulating layer ILp-2′ and the first preliminary insulating layer ILp-1′ may include a same material.

In an embodiment, the second preliminary insulating layer ILp-2′ may be formed in an entire area of the first to third emitting areas EA1, EA2, and EA3 and the non-emission area NEA.

Referring to FIG. 20, the pixel defining layer PDL and the pixel defining pattern PDP spaced apart from each other may be formed by patterning the second preliminary insulating layer ILp-2′. In an embodiment, the second preliminary insulating layer ILp-2′ may include a photoresist, and the pixel defining layer PDL and the pixel defining pattern PDP may be formed by exposing and developing the second preliminary insulating layer ILp-2′ using a photomask. In another embodiment, a photoresist pattern may be formed on the second preliminary insulating layer ILp-2′, and the pixel defining layer PDL and the pixel defining pattern PDP may be formed by partially etching the second preliminary insulating layer ILp-2′ using the photoresist pattern as an etching mask.

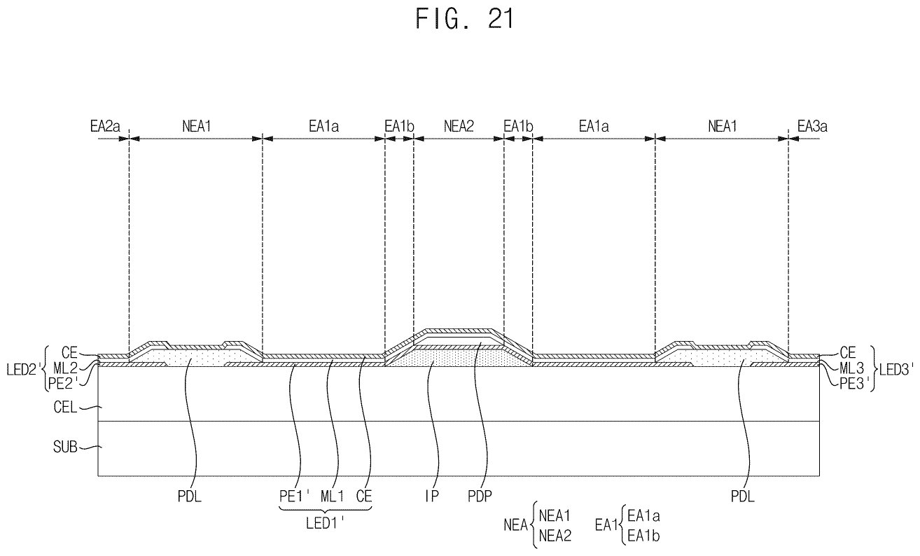

Referring to FIG. 21, the first to third intermediate layer ML1, ML2, and ML3 and the common electrode CE may be sequentially formed on the first to third pixel electrodes PE1′, PE2′, and PE3′, the pixel defining layer PDL, and the pixel defining pattern PDP.

The first to third intermediate layer ML1, ML2, and ML3 may include the first to third emission layers that emit light of different colors, respectively. The first to third emission layers may be formed to be spaced apart from each other to respectively correspond to the first to third emission areas EA1, EA2, and EA3. In an embodiment, the first to third emission layers may be formed only in areas corresponding to the first to third emission areas EA1, EA2, and EA3, respectively, using a deposition mask.

In an embodiment, the common electrode CE may be formed in an entire area of the first to third emission areas EA1, EA2, and EA3 and the non-emission area NEA.

The encapsulation layer ENC, the color filter layer, and the protective layer PL illustrated in FIG. 14 may be sequentially formed to manufacture the display device DD′.

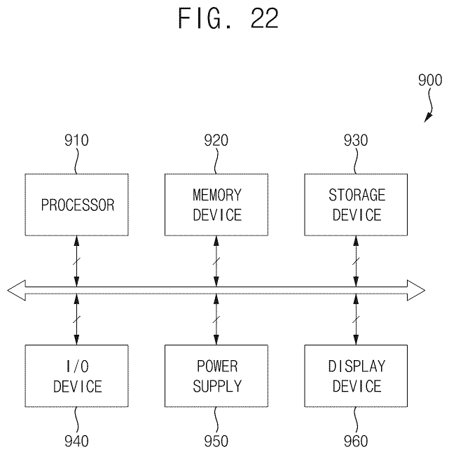

FIG. 22 is a schematic block diagram illustrating an electronic device according to an embodiment.

Referring to FIG. 22, in an embodiment, an electronic device 900 may include a processor 910, a memory device 920, a storage device 930, an input/output (“I/O”) device 940, a power supply 950, and a display device 960. The display device 960 may correspond to the display device DD of FIG. 3 or the display device DD′ of FIG. 14. The electronic device 900 may further include multiple ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, the disclosure is not limited thereto, and in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900.

The power supply 950 may provide power to the display device 960. The display device 960 may be coupled to other components via the buses or other communication links. In an embodiment, the display device 960 may be included in the I/O device 940.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a circuit element layer including a thin film transistor;
a pixel electrode disposed on the circuit element layer, electrically connected to the thin film transistor, and including a central portion, an outer portion outside the central portion in a plan view, and a first emission portion between the central portion and the outer portion;
an insulating pattern disposed between the circuit element layer and the central portion of the pixel electrode;
a pixel defining pattern disposed on the central portion of the pixel electrode;
a pixel defining layer disposed on the circuit element layer and the pixel electrode, covering the outer portion of the pixel electrode, and exposing the first emission portion of the pixel electrode;
an intermediate layer disposed on the pixel electrode, the pixel defining pattern, and the pixel defining layer, and including an emission layer; and
a common electrode disposed on the intermediate layer.

2. The display device of claim 1, wherein the pixel defining pattern covers the central portion of the pixel electrode and exposes the first emission portion of the pixel electrode.

3. The display device of claim 1, wherein in a plan view,
each of the insulating pattern and the pixel defining pattern has an island pattern shape, and
the pixel defining layer surrounds the central portion of the pixel electrode and the first emission portion of the pixel electrode.

4. The display device of claim 1, wherein in a plan view, the first emission portion surrounds the central portion, and the outer portion surrounds the first emission portion.

5. The display device of claim 1, wherein
the central portion of the pixel electrode is spaced apart from the intermediate layer with the pixel defining pattern interposed between the central portion of the pixel electrode and the intermediate layer,
the outer portion of the pixel electrode is spaced apart from the intermediate layer with the pixel defining layer interposed between the outer portion of the pixel electrode and the intermediate layer, and
the first emission portion of the pixel electrode contacts the intermediate layer.

6. The display device of claim 1, wherein in a plan view, the pixel defining layer is spaced apart from the pixel defining pattern and surrounds the pixel defining pattern.

7. The display device of claim 1, wherein in a plan view
the first emission portion of the pixel electrode is located outside the insulating pattern, and
the insulating pattern includes a flat portion and an inclined portion outside the flat portion.

8. The display device of claim 7, wherein
the pixel electrode further includes a second emission portion between the central portion and the first emission portion,
the central portion of the pixel electrode is located on the flat portion of the insulating pattern, and
the second emission portion of the pixel electrode is located on the inclined portion of the insulating pattern.

9. The display device of claim 8, wherein the second emission portion of the pixel electrode is inclined along an inclined surface of the inclined portion of the insulating pattern and contacts the intermediate layer.

10. The display device of claim 8, wherein the pixel defining pattern covers the central portion of the pixel electrode and exposes the second emission portion of the pixel electrode.

11. The display device of claim 8, wherein in a plan view, the second emission portion surrounds the central portion, and the first emission portion surrounds the second emission portion.

12. The display device of claim 1, further comprising:
an insulating layer disposed between the circuit element layer and the outer portion of the pixel electrode and between the circuit element layer and the pixel defining layer, and including a flat portion and an inclined portion outside the flat portion in a plan view, and
wherein the first emission portion of the pixel electrode is located between the insulating pattern and the insulating layer.

13. The display device of claim 12, wherein in a plan view,
each of the insulating pattern and the pixel defining pattern has an island pattern shape, and
each of the insulating layer and the pixel defining layer surrounds the central portion of the pixel electrode and the first emission portion of the pixel electrode.

14. The display device of claim 12, wherein in a plan view, the insulating layer is spaced apart from the insulating pattern and surrounds the insulating pattern.

15. The display device of claim 12, wherein
the pixel electrode further includes a third emission portion between the outer portion and the first emission portion,
the outer portion of the pixel electrode is located on the flat portion of the insulating layer, and
the third emission portion of the pixel electrode is located on the inclined portion of the insulating layer.

16. The display device of claim 15, wherein the third emission portion of the pixel electrode is inclined along an inclined surface of the inclined portion of the insulating layer and contacts the intermediate layer.

17. The display device of claim 15, wherein the pixel defining layer exposes the third emission portion of the pixel electrode.

18. The display device of claim 15, wherein in a plan view, the third emission portion surrounds the first emission portion, and the outer portion surrounds the third emission portion.

19. The display device of claim 1, further comprising:
an encapsulation layer disposed on the common electrode;
a light blocking layer disposed on the encapsulation layer in a cross-sectional view and overlapping the pixel defining layer in a plan view;
a light blocking pattern disposed on the encapsulation layer in a cross-sectional view and overlapping the pixel defining pattern in a plan view; and
a color filter disposed on the encapsulation layer in a cross-sectional view and overlapping the pixel electrode in a plan view.

20. A method of manufacturing a display device, the method comprising:
forming, on a substrate, a circuit element layer including a thin film transistor;
forming an insulating pattern on the circuit element layer;
forming, on the circuit element layer, a pixel electrode including a central portion on the insulating pattern, an outer portion outside the central portion in a plan view, and an emission portion between the central portion and the outer portion;
forming a preliminary insulating layer on the circuit element layer and the pixel electrode;
forming a pixel defining pattern on the central portion of the pixel electrode and a pixel defining layer covering the outer portion of the pixel electrode and exposing the emission portion of the pixel electrode by patterning the preliminary insulating layer;
forming, on the pixel electrode, the pixel defining pattern, and the pixel defining layer, an intermediate layer including an emission layer; and
forming a common electrode on the intermediate layer.

21. An electronic device comprising:
a display device; and
a power supply configured to provide power to the display device,
wherein the display device comprises:
a circuit element layer including a thin film transistor;
a pixel electrode disposed on the circuit element layer, electrically connected to the thin film transistor, and including a central portion, an outer portion outside the central portion in a plan view, and a first emission portion between the central portion and the outer portion;
an insulating pattern disposed between the circuit element layer and the central portion of the pixel electrode;
a pixel defining pattern disposed on the central portion of the pixel electrode;
a pixel defining layer disposed on the circuit element layer and the pixel electrode, covering the outer portion of the pixel electrode, and exposing the first emission portion of the pixel electrode;
an intermediate layer disposed on the pixel electrode, the pixel defining pattern, and the pixel defining layer, and including an emission layer; and
a common electrode disposed on the intermediate layer.
